(19) United States
(12) Patent Application Publication
(10) Pub. No.: US 2008/0169571 A1
(43) Pub. Date: Jul. 17, 2008

(54) SEMICONDUCTOR DEVICE AND METHOD FOR MANUFACTURING THE SAME

(75) Inventor: Kazutoshi IZUMI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/014,858

(22) Filed: Jan. 16, 2008

(30) Foreign Application Priority Data
Jan. 17, 2007 (JP) 2007-007920

(51) Int. Cl. H01L 23/48; H01L 21/00; H01L 21/44; H01L 21/461

(52) U.S. Cl. 257/774; 438/3; 438/667; 438/692; 257/E21.001; 257/E23.01; 257/E21.476; 257/E21.483

(57) ABSTRACT

A semiconductor device, and a method for manufacturing the semiconductor device, has forming a layer having an in-plane polishing amount distribution, and setting the approximate uniform thickness of the layer over the whole semiconductor wafer by the process such that the in-plane polishing amount distribution is approximately uniform.

### TECHNICAL FIELD

The present invention generally relates to semiconductor devices, and more particularly relates to a semiconductor device having elements in contact with wire layers through via holes provided in an interlayer insulating film and to a method for manufacturing the semiconductor device.

### BACKGROUND

In recent semiconductor devices having an improved integration density, complicated wiring is required, and a multilayer wiring structure including a plurality of interlayer insulating films which are laminated to each other is used in many cases. In the multilayer wiring structure including laminated interlayer insulating films as described above, in order to connect an active element formed on a substrate to a wire layer, deep via plugs are used.

In addition, in a recent ferroelectric memory device having a ferroelectric capacitor, it is preferable that the ferroelectric capacitor, which must be processed in an oxidizing atmosphere, be separated from an active element, which is to be processed in a reducing atmosphere, as much as possible. Accordingly, in general, a plurality of interlayer insulating films is formed on a silicon substrate on which active elements are formed, and on the interlayer insulating films described above, ferroelectric capacitors are formed. In the ferroelectric memory device as described above, a technique forming deep via plugs in a multilayer wiring structure is required (for example, see Japanese Unexamined Patent Application Publication Nos. Hei 11-111683 and Hei 7-66291).

### SUMMARY

According to the present invention, there is provided a semiconductor device, and a method for manufacturing the semiconductor device, forming a layer having an in-plane polishing amount distribution, and setting the approximate uniform thickness of the layer over the whole semiconductor wafer by the process such that the in-plane polishing amount distribution is approximately uniform.

### BRIEF DESCRIPTION OF THE DRAWINGS

FIG. 1 is a cross-sectional view of a ferroelectric memory structure by a related technique of the present invention;

FIG. 2 is a graph illustrating the principle of the present invention;

FIG. 3 is another graph illustrating the principle of the present invention;

FIGS. 4A to 4C are views illustrating an object of the present invention;

FIGS. 5A to 5C are views showing the structure of a semiconductor device according to a First embodiment of the present invention;

FIGS. 6A to 6I are views showing a step of manufacturing the semiconductor device according to the first embodiment;

FIGS. 7A and 7B are flowcharts showing a process for manufacturing the semiconductor device according to the first embodiment;

FIGS. 8A and 8B are cross-sectional views each showing the structure of the semiconductor device according to the first embodiment of the present invention;

FIGS. 9A and 9B are electron microscope photographs each showing a cross-section of via plugs of the semiconductor device according to the first embodiment of the present invention;

FIGS. 10A to 10E are views showing a step of manufacturing a semiconductor device according to a second embodiment of the present invention;

FIGS. 11A and 11B are views showing a deposition apparatus used in the second embodiment and a substrate temperature distribution, respectively;

FIGS. 12A to 12B are flowcharts showing a process for manufacturing the semiconductor device according to the second embodiment;

FIG. 13 is a graph illustrating an in-plane thickness distribution of a W film formed on an interlayer insulating film relating to a third embodiment of the present invention;

FIGS. 14A to 14C are views showing a step of manufacturing a semiconductor device according to the third embodiment of the present invention;

FIGS. 15A and 15B are views showing a step of manufacturing the semiconductor device according to the third embodiment of the present invention;

FIGS. 16A and 16B are views showing one modified example according to the third embodiment;

FIGS. 17A and 17B are flowcharts showing a process for manufacturing the semiconductor device according to the third embodiment.

### DETAILED DESCRIPTION OF THE EMBODIMENTS

### First Embodiment

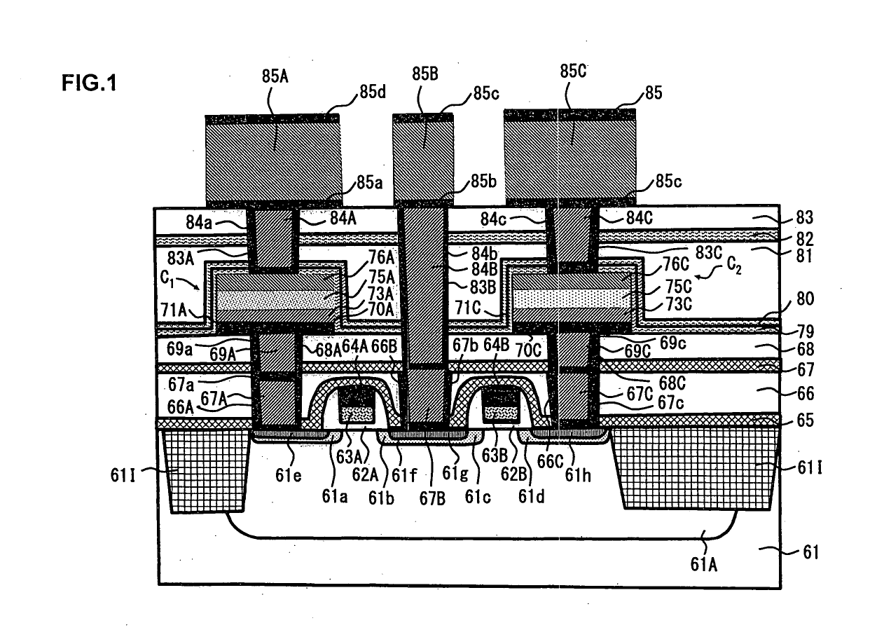

FIG. 1 is a cross-sectional view showing a ferroelectric memory 60 formed on a silicon substrate 61 by a related technique of the present invention.

As shown in FIG. 1, an n-type well is formed in the silicon substrate 61 as an element region 61A. A first MOS transistor having a polysilicon gate electrode 63A and a second MOS transistor having a polysilicon gate electrode 63B are formed on the element region 61A with gate insulating films 62A and 62B interposed therebetween, respectively.

Furthermore, in the silicon substrate 61, p -type lightly doped drain (hereinafter referred to as “LDD”) regions 61a and 61b are formed so as to correspond to two sidewall surfaces of the gate electrode 63A. In addition, p -type LDD regions 61c and 61d are formed so as to correspond to two sidewall surfaces of the gate electrode 63B. In this case, since the first and the second MOS transistors are formed in the same element region 61A, the same p -type diffusion region is commonly used as both the LDD regions 61b and 61c.

Silicide layers 64A and 64B are formed on the polysilicon gate electrodes 63A and 63B, respectively. Furthermore, sidewall insulating films are formed on the two sidewall surfaces of each of the polysilicon gate electrodes 63A and 63B.

Furthermore, in the silicon substrate 61, p -type diffusion regions 61e and 61f are formed outside the respective sidewall insulating films of the gate electrode 63A. In addition, p -type diffusion regions 61g and 61h are formed outside the respective sidewall insulating films of the gate electrode 63B. However, the diffusion regions 61f and 61g are formed from the same p -type diffusion region.

Furthermore, a SiON film 65 having a thickness of 200 nm or the like is formed on the silicon substrate 61 so as to cover the gate electrode 63A including the silicide layer 64A and the sidewall insulating films. In addition, the SiON film 65 having a thickness of 200 nm or the like is formed so as to cover the gate electrode 63B including the silicide layer 64B and the sidewall insulating films. On the SiON film 65, an interlayer insulating film 66 of SiO₂ is formed to have a thickness of 1,000 nm or the like by a plasma CVD method using tetraethoxysilane (hereinafter referred to as “TEOS” in some cases) as a raw material. Furthermore, the interlayer insulating film 66 is planarized by a chemical mechanical polishing (CMP) method. In addition, in the interlayer insulating film 66, contact holes 66A, 66B, and 66C are formed so as to expose the diffusion regions 61e, 61f (that is, the diffusion region 61g), and 61h. In the contact holes 66A, 66B, and 66C, via plugs 67A, 67B, and 67C are formed with adhesion layers 67a, 67b, and 67c interposed therebetween, respectively. The adhesion layers 67a, 67b, and 67c are each a laminate composed of a Ti film having a thickness of 30 nm and a TiN layer having a thickness of 20 nm. The via plugs 67A, 67B, and 67C are formed of tungsten (W).

Furthermore, in the structure shown in FIG. 1, on the interlayer insulating film 66, a second interlayer insulating film 68 made of silicon oxide is formed with another SiON film 67 interposed therebetween. The SiON film 67 functions as an oxygen barrier. The thickness of the SiON film 67 is, for example, 130 nm. In addition, as is the interlayer insulating film 66, the interlayer insulating film 68 is formed to have a thickness of 300 nm or the like by a plasma CVD method using TEOS as a raw material.

Furthermore, in the interlayer insulating film 68, via holes 68A and 68C are formed so as to expose the via plugs 67A and 67C, respectively. A via plug 69A is formed in the via hole 68A with an adhesion layer 69a interposed therebetween so as to be in contact with the via plug 67A. The adhesion layer 69a is formed by laminating a Ti film and a TiN film. The via plug 69A is formed of tungsten. In addition, a via plug 69C is formed in the via hole 68C with an adhesion layer 69c interposed therebetween so as to be in contact with the via plug 67C. The adhesion layer 69c is formed by laminating a Ti film and a TiN film. The via plug 69C is formed of tungsten.

Furthermore, on the interlayer insulating film 68 and on the via plug 69A, a TiN film pattern 70A, a TiAlN film pattern 71A, and a Pt lower electrode pattern 73A are formed in that order from the bottom. The TiN film pattern 70A, the TiAlN film pattern 71A, and the Pt lower electrode pattern 73A are all formed to have the (111) orientation.

Furthermore, on the Pt lower electrode pattern 73A, a PZT film pattern 75A having the (111) orientation is formed to have a thickness of 80 nm or the like. On the PZT film pattern 75A, an upper electrode pattern 76A made of IrOₓ is formed.

In this embodiment, the lower electrode pattern 73A, the PZT film pattern 75A, and the upper electrode pattern 76A form a ferroelectric capacitor C1. The upper surface and the side surfaces of the ferroelectric capacitor C1 including the TiN film pattern 70A and the TiAlN film pattern 71A provided thereunder are covered with Al₂O₃-made hydrogen barrier films 79 and 80.

As is the case described above, on the interlayer insulating film 68 and on the via plug 69C, a TiN film pattern 70C, a TiAlN film pattern 71C, and a Pt lower electrode pattern 73C are formed in that order from the bottom. The TiN film pattern 70C, the TiAlN film pattern 71C, and the Pt lower electrode pattern 73C are all formed to have the (111) orientation.

Furthermore, on the Pt lower electrode pattern 73C, a PZT film pattern 75C having the (111) orientation is formed to have a thickness of 80 nm or the like. On the PZT film pattern 75C, an upper electrode pattern 76C made of IrOₓ is formed.

The lower electrode pattern 73C, the PZT film pattern 75C, and the upper electrode pattern 76C form a ferroelectric capacitor C2. The upper surface and the side surfaces of the ferroelectric capacitor C2 including the TiN film pattern 70C and the TiAlN film pattern 71C provided thereunder are covered with the aforementioned Al₂O₃-made hydrogen barrier films 79 and 80.

Furthermore, an interlayer insulating film 81 made of silicon oxide is formed on the above Al₂O₃-made hydrogen barrier film 80 so as to cover the ferroelectric capacitors C1 and C2. On the interlayer insulating film 81, an interlayer insulating film 83 is formed with an Al₂O₃-made hydrogen barrier film 82 interposed therebetween.

In addition, in the interlayer insulating films 81 and 83, contact holes 83A and 83C are formed so as to penetrate the Al₂O₃ films 79, 80, and 82. The contact holes 83A and 83C are formed so as to expose the upper electrode 76A of the ferroelectric capacitor C1 and the upper electrode 76C of the ferroelectric capacitor C2, respectively. In the contact hole 83A, a W plug 84A is formed with a barrier metal film 84a of a Ti/TiN laminate structure interposed therebetween. In addition, in the contact holes 83C, a W plug 84C is formed with a barrier metal film 84c of a Ti/TiN laminate structure interposed therebetween.

In addition, a contact hole 83B is formed in the interlayer insulating films 81, and 83 so as to penetrate the SiON film 67 and the Al₂O₃ films 79, 80, and 82. The contact hole 83B exposes the via plug 67B. In the contact hole 83B, a W plug 84B is formed with a barrier metal film 84b of a Ti/TiN laminate structure interposed therebetween.

Furthermore, on the interlayer insulating film 83, a wire pattern 85A of an AlCu alloy is provided corresponding to the via plug 84A so as to be sandwiched with adhesion films 85a and 85d each having a Ti/TiN laminate structure. A wire pattern 85B of an AlCu alloy is provided corresponding to the via plug 84B so as to be sandwiched with adhesion films 85b and 85e each having a Ti/TiN laminate structure. In addition, A wire pattern 85C of an AlCu alloy is provided corresponding to the via plug 84C so as to be sandwiched with adhesion films 85c and 85f each having a Ti/TiN laminate structure.

In the ferroelectric memory shown in FIG. 1, for example, when the via plugs 69A and 69C are formed in the interlayer insulating film 68, the following damascene process is performed. First, the via holes 68A and 68C are formed in the interlayer insulating film 68 for the via plugs 69A and 69C, respectively. Next, the via holes 68A and 68C are covered with a barrier metal film and are then filled with a metal such as W by a CVD method. Subsequently, an excess metal film on the surface of the interlayer insulating film 68 is removed by a CMP method. In addition, a damascene process is not only performed for forming a ferroelectric memory but also is performed for forming a wire layer in a multilayer wire structure.

In addition, the damascene process as described above is performed after individual semiconductor devices are formed on a semiconductor wafer. Hence, the above CMP step is also simultaneously performed for all the semiconductor devices formed on the semiconductor wafer.

However, polishing properties of a CMP step may change in some cases, in particular in the radius direction of a semiconductor wafer, depending on types of CMP apparatuses and polishing conditions. For example, when a CMP apparatus manufactured by one producer is used, the polishing amount in the vicinity of a wafer central portion and that in the vicinity of a wafer peripheral portion may be different in some cases.

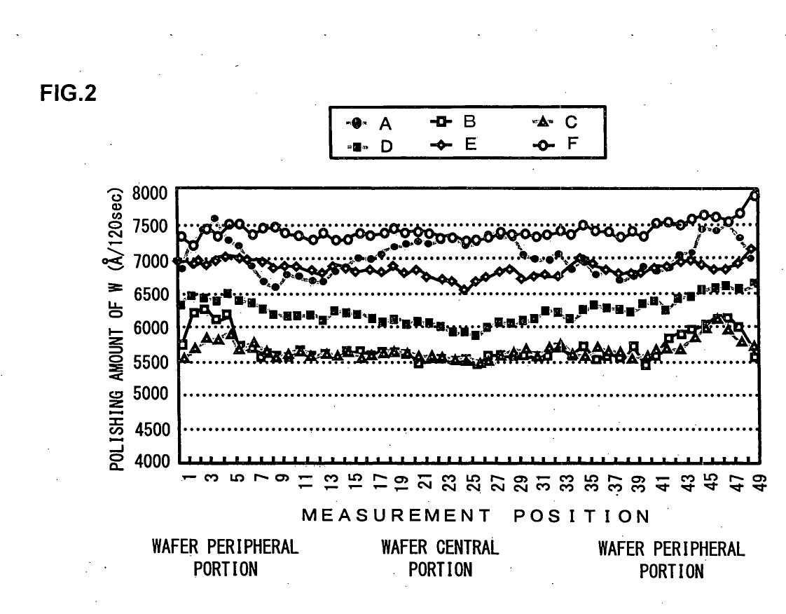

FIG. 2 is a graph showing in-plane polishing amount distributions which were obtained when an oxide (e.g. SiON and Al₂O₃) film, W (tungsten) on a TiN film, and a silicon oxide film each having a diameter of 20 cm, were polished under various polishing conditions using a CMP apparatus manufactured by an A company, the in-plane polishing amount distributions being found through fundamental research of the present invention which was carried out by the inventor of the present invention.

In FIG. 2, “A” indicates an in-plane polishing amount distribution which was obtained under the conditions in which a polishing pressure was set to 3 psi, a polishing disc was rotated at 100 rpm, and a sample was rotated at 100 rpm. As a polishing agent, a slurry containing silica particles was used. As a polishing pad, a foamed (polyurethane) resin was used. In this experiment, only a liquid concentrate of the slurry was used. Hydrogen peroxide (H₂O₂) was added to the liquid concentrate of the slurry in an amount of 1 percent by weight with respect thereto.

In addition, “B” indicates an in-plane polishing amount distribution which was obtained under the conditions in which the polishing pressure was set to 3 psi, the polishing disc was rotated at 100 rpm, and the sample was rotated at 100 rpm. As the polishing agent, a slurry containing silica particles was used. As the polishing pad, a foamed (polyurethane) resin was used. In this experiment, as the polishing agent, the liquid concentrate of the slurry was diluted with water at a ratio of 1 to 1.

Furthermore, “C” indicates an in-plane polishing amount distribution which was obtained under the conditions in which the polishing pressure was set to 3.3 psi, the polishing disc was rotated at 100 rpm, and the sample was rotated at 100 rpm. As the polishing agent, a slurry containing silica particles was used. As the polishing pad, a foamed (polyurethane) resin was used. In this experiment, as the polishing agent, the slurry containing silica particles was diluted with water at a ratio of 1 to 1.

“D” indicates an in-plane polishing amount distribution which was obtained under the conditions in which the polishing pressure was set to 3.6 psi, the polishing disc was rotated at 100 rpm, and the sample was rotated at 100 rpm. As the polishing agent, a slurry containing silica particles was used. As the polishing pad, a foamed (polyurethane) resin was used. Also in this experiment, as the polishing agent, the slurry containing silica particles was diluted with water at a ratio of 1 to 1.

“E” indicates an in-plane polishing amount distribution which was obtained under the conditions in which the polishing pressure was set to 3.9 psi, the polishing disc was rotated at 100 rpm, and the sample was rotated at 100 rpm. As the polishing agent, a slurry containing silica particles was used. As the polishing pad, a foamed (polyurethane) resin was used. Also in this experiment, as the polishing agent, the slurry containing silica particles was diluted with water at a ratio of 1 to 1.

“F” indicates an in-plane polishing amount distribution which was obtained under the conditions in which the polishing pressure was set to 4.2 psi, the polishing disc was rotated at 100 rpm, and the sample was rotated at 100 rpm. As the polishing agent, a slurry containing silica particles was used. As the polishing pad, a foamed (polyurethane) resin was used. Also in this experiment, as the polishing agent, the slurry containing silica particles was diluted with water at a ratio of 1 to 1.

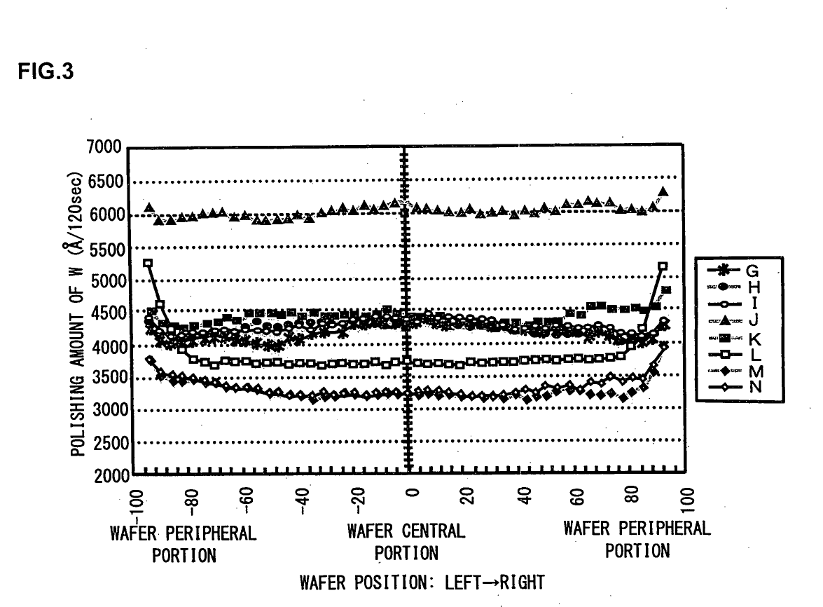

FIG. 3 is a graph showing in-plane polishing amount distributions which were obtained when a silicon oxide film on a silicon substrate having a diameter of 20 cm was polished under various polishing conditions using a CMP apparatus manufactured by a B company, the in-plane polishing amount distributions being found through the fundamental research of the present invention carried out by the inventor of the present invention.

FIG. 3 shows the case in which chemical mechanical polishing was performed using an apparatus manufactured by a different producer. For example, as the polishing agent, a slurry containing silica particles was used for “G”. As the polishing pad, a foamed (polyurethane) resin was used. “G” indicates an in-plane polishing amount distribution which was obtained under conditions in which the polishing pressure was set to 8 psi, the polishing disc was rotated at 60 rpm, and the sample was rotated at 60 rpm.

As shown in the graphs, in the CMP step, variation in polishing amount in the radius direction may occur in some cases by polishing conditions and polishing apparatuses. When the variation as described above occurs, a semiconductor device obtained from a wafer central portion and a semiconductor device obtained from a wafer peripheral portion may disadvantageously have different properties in some cases. Alternatively, the yields between the above two portions may disadvantageously differ from each other in some cases.

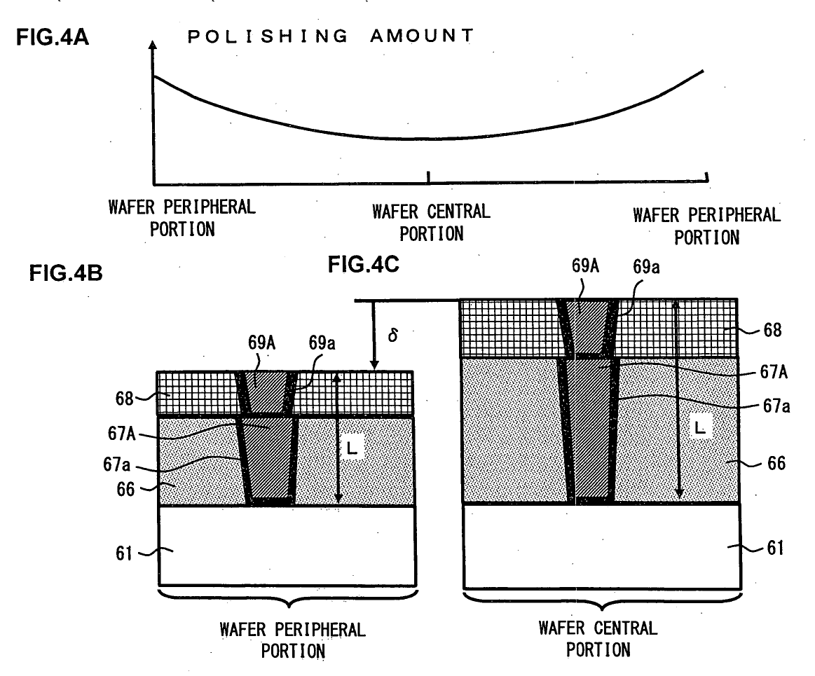

FIG. 4A is a graph showing an example of an in-plane polishing amount distribution in which the polishing amount is small at a wafer central portion and is large at a wafer peripheral portion.

FIG. 4B is a view showing the state of via plugs formed in the wafer peripheral portion in the case in which the via plugs 67A and 69A of the ferroelectric memory shown in FIG. 1 were formed using a CMP apparatus having the in-plane polishing amount distribution shown in FIG. 4A.

FIG. 4C is a view showing the state of via plugs formed in the wafer central portion in the case in which the via plugs 67A and 69A of the ferroelectric memory shown in FIG. 1 were formed using the CMP apparatus having the in-plane polishing amount distribution shown in FIG. 4A.

As shown in FIGS. 4B and 4C, since the polishing amount of the CMP apparatus is larger at the waver peripheral portion, by the damascene process forming the via plug 67A and the damascene process forming the via plug 69A, the interlayer insulating films 66 and 68 are polished in a larger amount at the wafer peripheral portion. As a result, a total length L of the via plugs 67A and 69A is small at the wafer peripheral portion and is large at the wafer central portion, and hence it is understood that the difference δ is generated.

On the other hand, in the case in which the polishing amount is large at the wafer central portion and is small at the wafer peripheral portion, the structure shown in FIG. 4B is formed at the wafer central portion and the structure shown in FIG. 4C is formed at the wafer peripheral portion.

As described above, the total length L of the via plugs 67A and 69A or the total length L of the via plugs 67C and 69c at the wafer central portion may be different from that at the wafer peripheral portion in some cases. In the case described above, the properties, such as the inductance of the via plug, may vary between a semiconductor device obtained from the wafer peripheral portion and a semiconductor device obtained from the wafer central portion in some cases. Consequently, the manufacturing yield of semiconductor devices may be degraded.

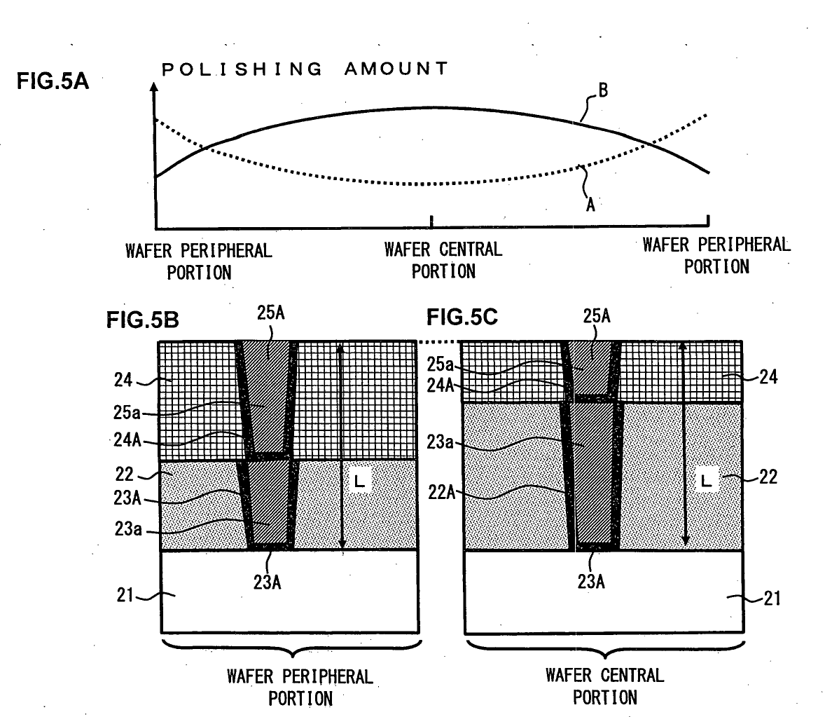

FIGS. 5A to 5C are views showing a first embodiment of the present invention. FIG. 5A is a view showing in-plane polishing amount distributions of CMP apparatuses A and B used in this embodiment. FIG. 5B is a view showing the structure of a semiconductor device obtained from a wafer peripheral portion according to this embodiment. FIG. 5C is a view showing the structure of a semiconductor device obtained from a wafer central portion according to this embodiment.

As shown in FIG. 5A, the CMP apparatus A has an in-plane polishing amount distribution shown by a curve “A” in which the polishing amount is small at the wafer central portion and is large at the wafer peripheral portion. On the other hand, the CMP apparatus B has an in-plane polishing amount distribution shown by a curve “B” in which the polishing amount is small at the wafer peripheral portion and is large at the wafer central portion.

In this embodiment, as shown in FIGS. 5B and 5C, interlayer insulating films 22 and 24 are formed on a substrate 21. When via plug 23A and 25A are formed in the respective interlayer insulating films, CMP of the interlayer insulating film 22 is performed by the CMP apparatus A, and CMP of the interlayer insulating film 24 is performed by the CMP apparatus B. By the steps as described above, a total thickness L of the interlayer insulating films 22 and 24 is formed so as to be approximately uniform from the wafer central portion to the wafer peripheral portion.

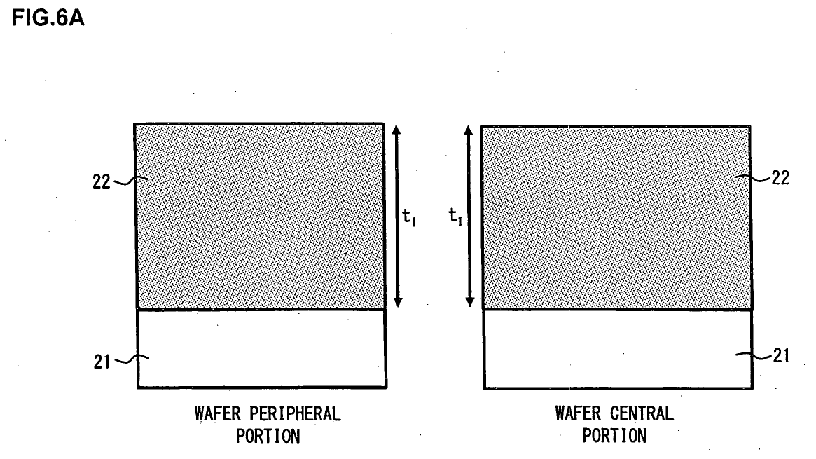

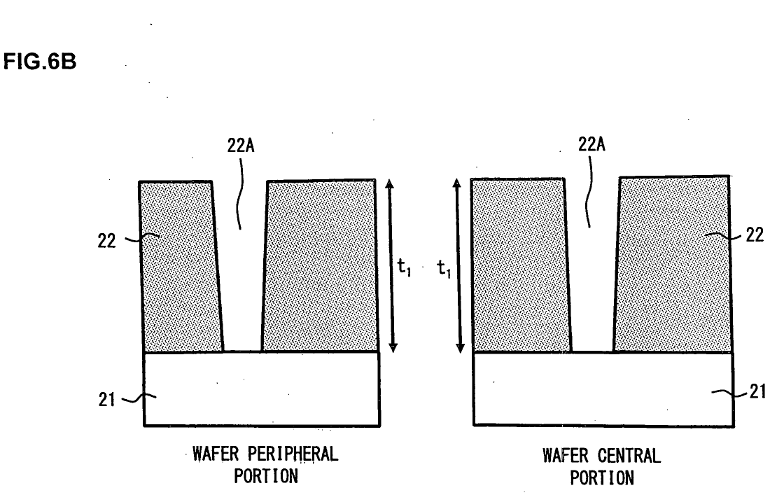

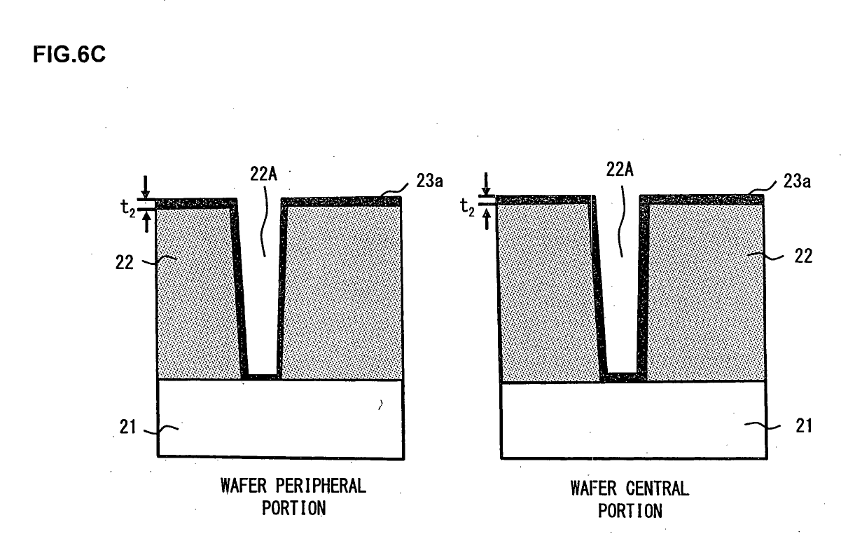

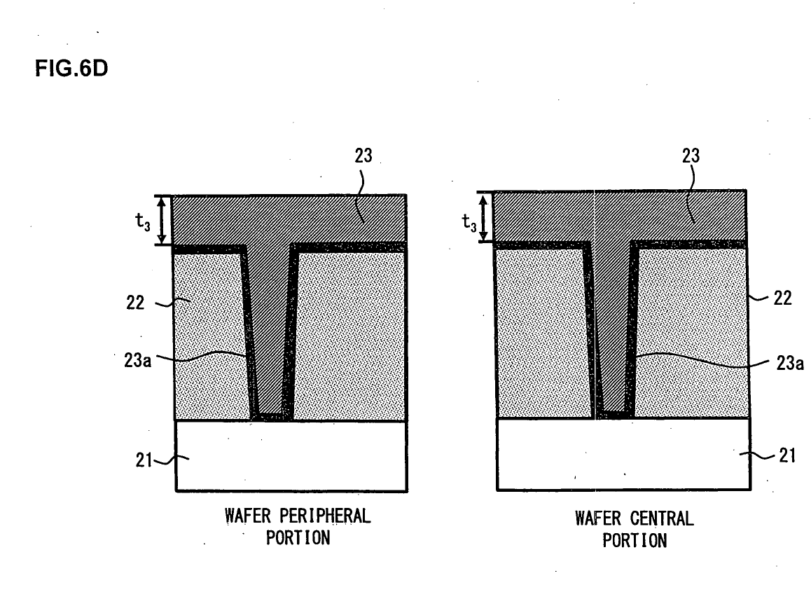

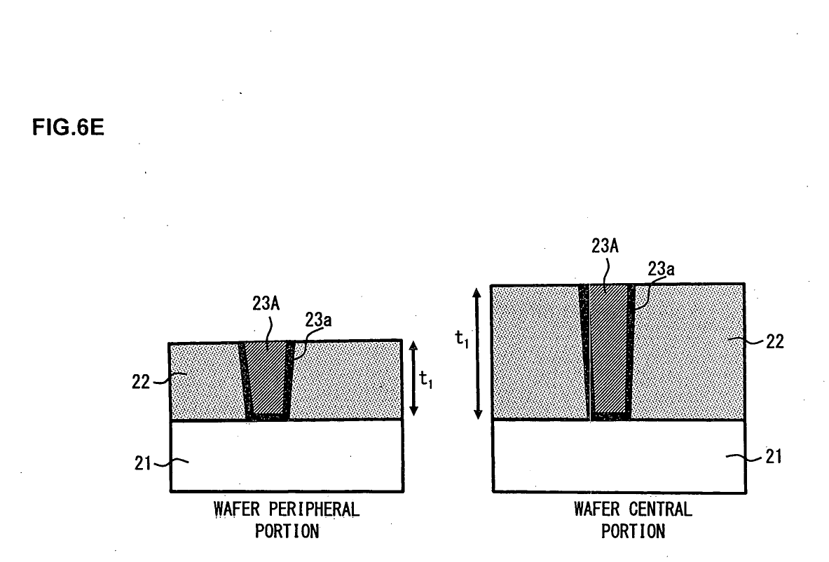

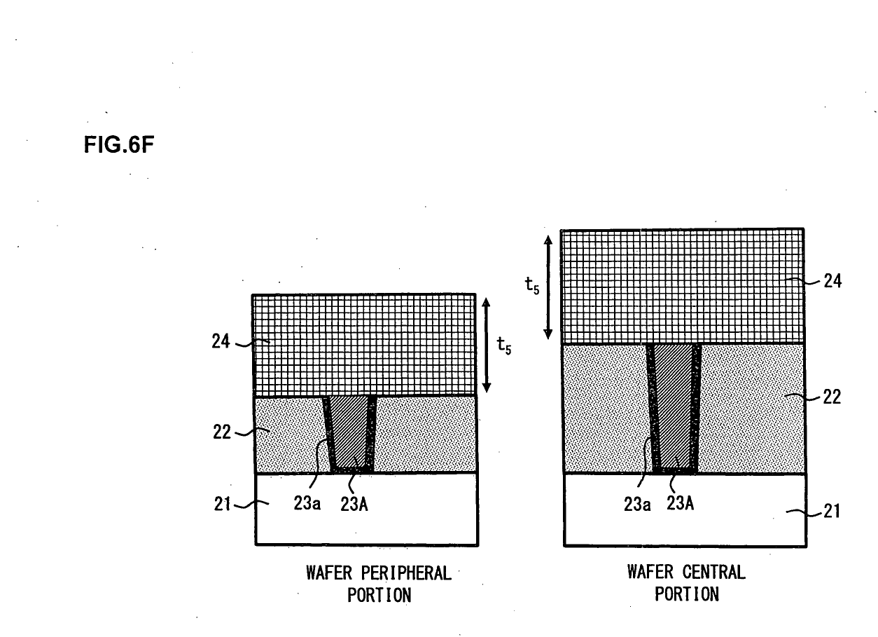

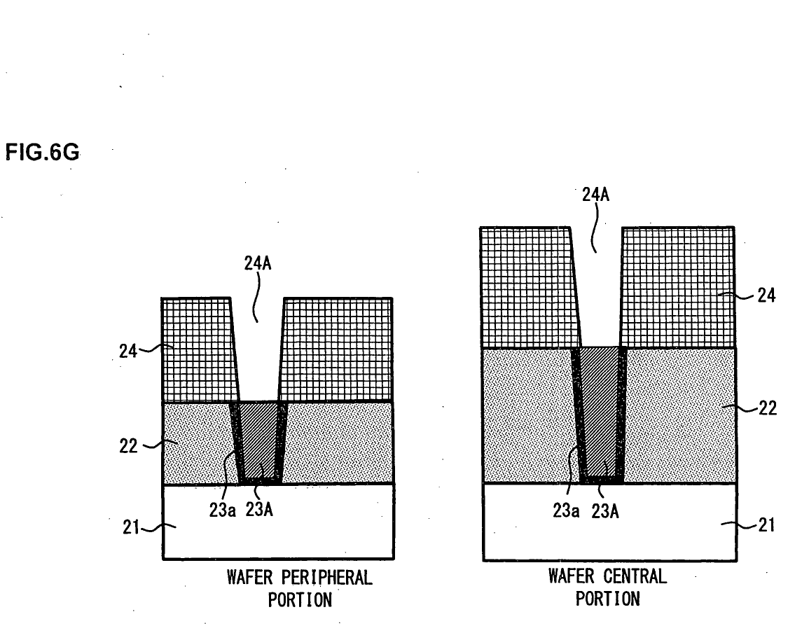

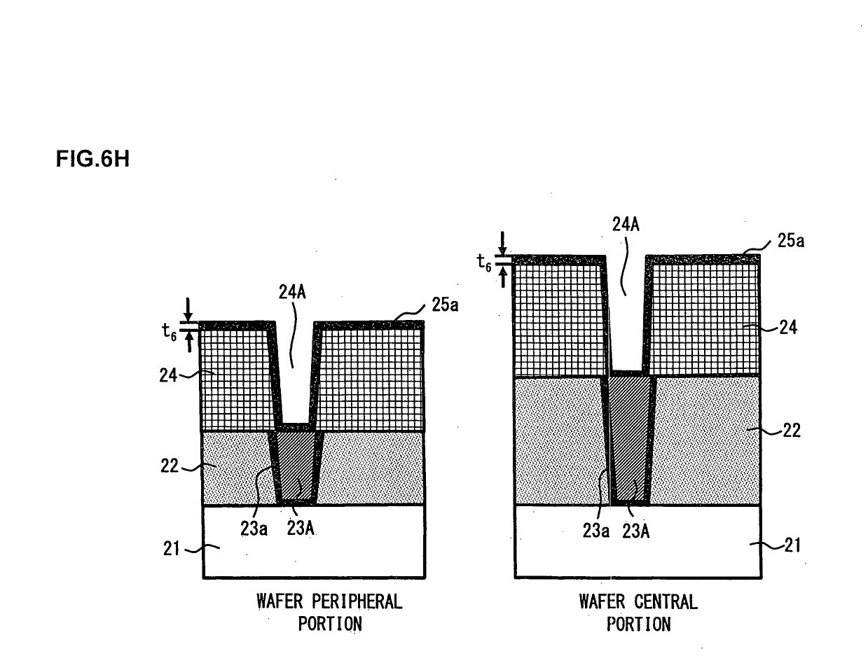

FIGS. 6A to 6I show steps of forming the structures shown in FIGS. 5B and 5C.

As shown in FIG. 6A, the first interlayer insulating film 22 is formed on the substrate 21 so as to have a thickness t1, such as 700 nm, which is approximately uniform from the wafer central portion to the wafer peripheral portion. In the step shown in FIG. 6B, via holes 22A are formed in the above interlayer insulating film 22 to have a depth t1 both at the wafer peripheral portion and at the wafer central portion. The step of forming the interlayer insulating film 22 is not limited to a specific process. For example, in this embodiment, the interlayer insulating film 22 is formed by a plasma CVD method using TEOS as a raw material.

Furthermore, in the step shown in FIG. 6C, on the interlayer insulating film 22, a barrier metal film 23a is formed, for example, by a sputtering method so as to cover inner wall surfaces and bottom surfaces of the via holes 22A. The barrier metal film 23a has, for example, a Ti/TiN laminate structure. The barrier metal film 23a is formed to have a thickness t2 of 50 nm both at the wafer peripheral and at the wafer central portions.

In the step shown in FIG. 6D, a W film 23 is formed on the structure shown in FIG. 6C, for example, by a CVD method using WF₆ as a raw material so as to fill the via holes 22A and cover the interlayer insulating film 22 with the barrier metal film 23a interposed therebetween. The W film 23 is formed to have a thickness t3 of 200 nm or the like both at the wafer peripheral and at the wafer central portions.

Furthermore, according to this embodiment, in the step shown in FIG. 6E, the W film 23 on the interlayer insulating film 22 is polished and removed by a CMP method together with parts of the barrier metal film 23a and the interlayer insulating film 22, which are located under the W film 23.

According to the example shown in the figures, the CMP step shown in FIG. 6E was performed by a CMP apparatus named MIRRA manufactured by Applied Material Inc., and as a polishing pad, a foamed polyurethane manufactured by Nitta Hass Inc. was used. Water or a solvent containing 1 to 2 percent by weight of abrasive made of silica was used as a polishing agent. The rotation speed of a polishing disc was 100 rpm. Furthermore, an object sample to be polished was pressed onto the polishing pad at a pressure of 6 psi, and the CMP step was performed while the polishing disc was rotated at a speed of 100 rpm. When the W film 23 is polished by the CMP step described above, the in-plane polishing amount distribution shown by the curve A of the above FIG. 5A is obtained. As a result, the interlayer insulating film 22 has an in-plane distribution in which the thickness t1 is large at the central portion and is small at the peripheral portion as shown in FIG. 6E.

Next, in the step shown in FIG. 6F, the second interlayer insulating film 24 is formed on the structure shown in FIG. 6E, for example, by a plasma CVD method using TEOS as a raw material. The second interlayer insulating film 24 is formed to have a thickness t5 of 700 nm both at the wafer peripheral and the wafer central portions.

Furthermore, in the step shown in FIG. 6G, via holes 24A having a depth of t5 are formed in the interlayer insulating film 24 so as to expose the via plugs 23A. In the step shown in FIG. 6H, a barrier metal film 25a having a Ti/TiN laminate structure is formed on the structure shown in the above FIG. 6G by a sputtering method or the like so as to cover inner wall surfaces and bottom surfaces of the via holes 24A and so as to have a thickness of 50 nm both at the wafer peripheral and the wafer central portions.

Furthermore, in the step shown in FIG. 6I, a W film 25 is formed on the structure shown in the above FIG. 6H so as to fill the via holes 24A with the above barrier metal film 25a interposed therebetween. The W film 25 is formed, for example, by a CVD method using WF₆ as a raw material. In addition, the W film 25 on the interlayer insulating film 24 is formed to have a thickness t7 of 300 nm both at the wafer peripheral and the wafer central portions.

Furthermore, after the step shown in the above FIG. 6I, the W film 25 on the interlayer insulating film 24 are polished by a CMP method together with parts of the barrier metal film 25a and the interlayer insulating film 24, which are located under the W film 25.

According to the example shown in the figures, when the CMP step was performed after the step shown in FIG. 6I by an apparatus manufactured by another producer, as a polishing pad, a foamed polyurethane manufactured by Nitta Hass Inc. was used. Water or a solvent containing 1 to 2 percent by weight of abrasive made of silica was used as a polishing agent. By the apparatus used in the CMP step, the polishing was performed while a polishing disc was rotated at a speed of 100 rpm, and furthermore, while the object sample to be polished was pressed onto the polishing pad at a pressure of 6 psi and was rotated at a speed of 100 rpm. When the W film 25 is polished by the CMP step described above, the in-plane polishing amount distribution shown by the curve B of the above FIG. 5A is obtained so as to compensate for the in-plane polishing amount distribution shown by the curve A. As a result, as shown in FIGS. 5B and 5C, the surface of the interlayer insulating film 24 becomes flat. Hence, the total length L of the via plugs 23A and 25A can be made approximately uniform from the wafer peripheral portion to the wafer central portion.

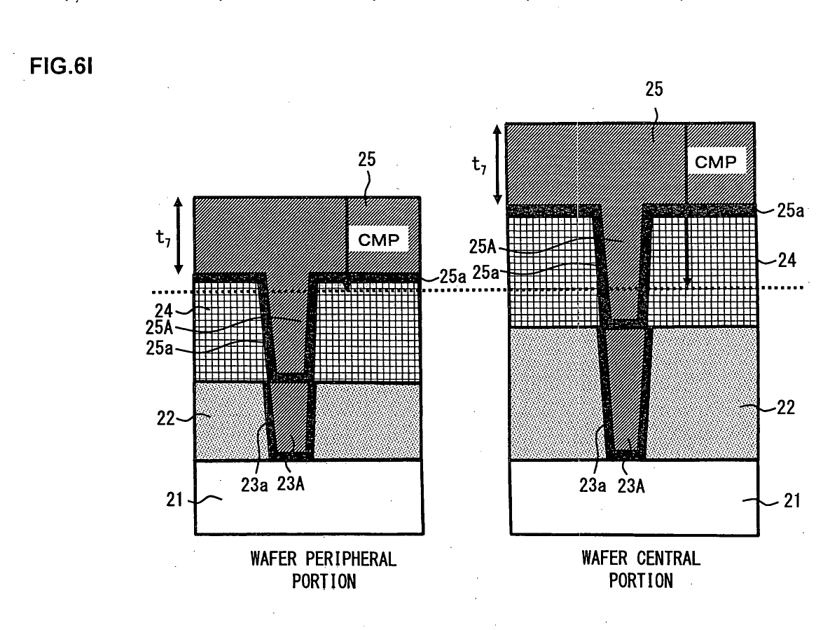

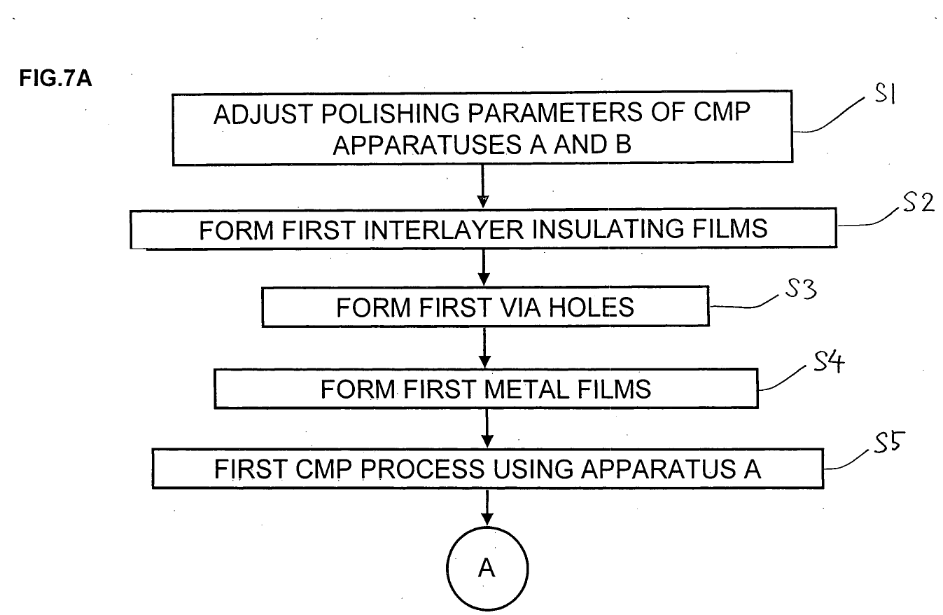

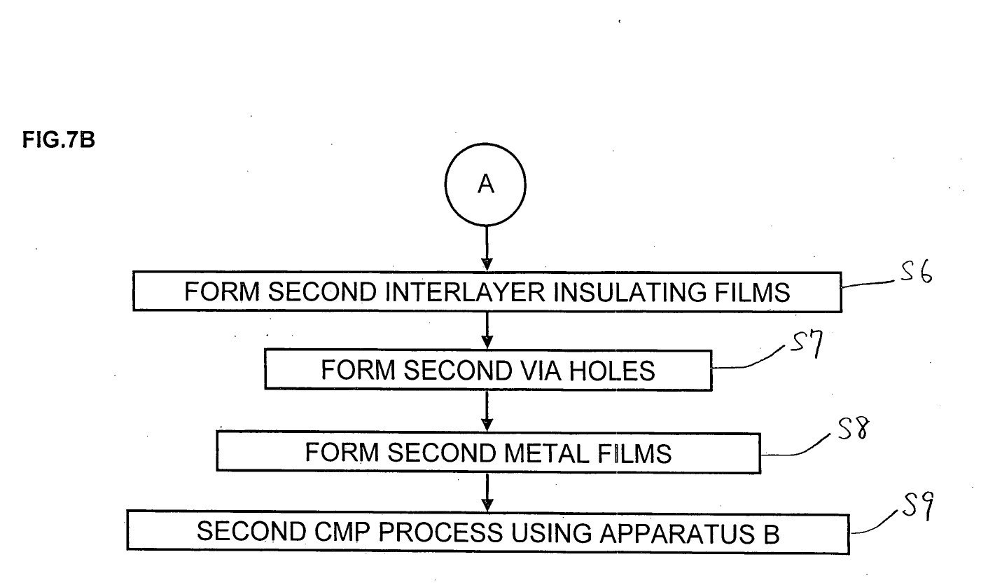

FIGS. 7A and 7B show schematic flowcharts of the first embodiment according to the present invention.

As shown in FIG. 7A, in Step S1 of this embodiment, first, polishing parameters of the CMP apparatuses A and B used in the CMP steps for the interlayer insulating films 22 and 24 are adjusted so as to be complementary to each other. The adjustment of the polishing parameters described above includes, for example, the selection of an apparatus itself as described above, selection of a polishing pad, selection of a polishing agent, setting of a polishing pressure, and setting of rotation speeds of a polishing disc and a sample.

Next, in Step S2, corresponding to the step shown in the above FIG. 6A, the first interlayer insulating film 22 is formed on the substrate. In Step S3, corresponding to the step shown in the above FIG. 6B, the via holes 22A are formed in the first interlayer insulating film 22.

Furthermore, in Step S4, corresponding to the steps shown in FIGS. 6C and 6D, the barrier metal film 23a and the W film 23 are formed. In Step S5, the W film 23 and the barrier metal film 23a are polished by a CMP method using the CMP apparatus A, so that the structure shown in FIG. 6E is formed.

Next, in Step S6 shown in FIG. 7B, the interlayer insulating film 24 is formed on the structure shown in FIG. 6E corresponding to the step shown in FIG. 6F. In Step S7, corresponding to the step shown in FIG. 6G, the via holes 24A are formed in the interlayer insulating film 24.

Furthermore, in Step S8, corresponding to the steps shown in FIGS. 6H and 6I, the barrier metal film 25a and the W film 25 are formed on the structure shown in FIG. 6G. In addition, in Step S9, the W film 25 and the barrier metal film 25a shown in FIG. 6I are polished by a CMP method using the CMP apparatus B.

In the case described above, the polishing properties of the CMP apparatuses A and B are adjusted in Step S1 so as to be complementary to each other. Hence, the total thickness of the interlayer insulating films 22 and 24 is approximately uniform from the wafer peripheral portion to the wafer central portion, and as a result, the structure described with reference to the above FIGS. 5B and 5C can be obtained.

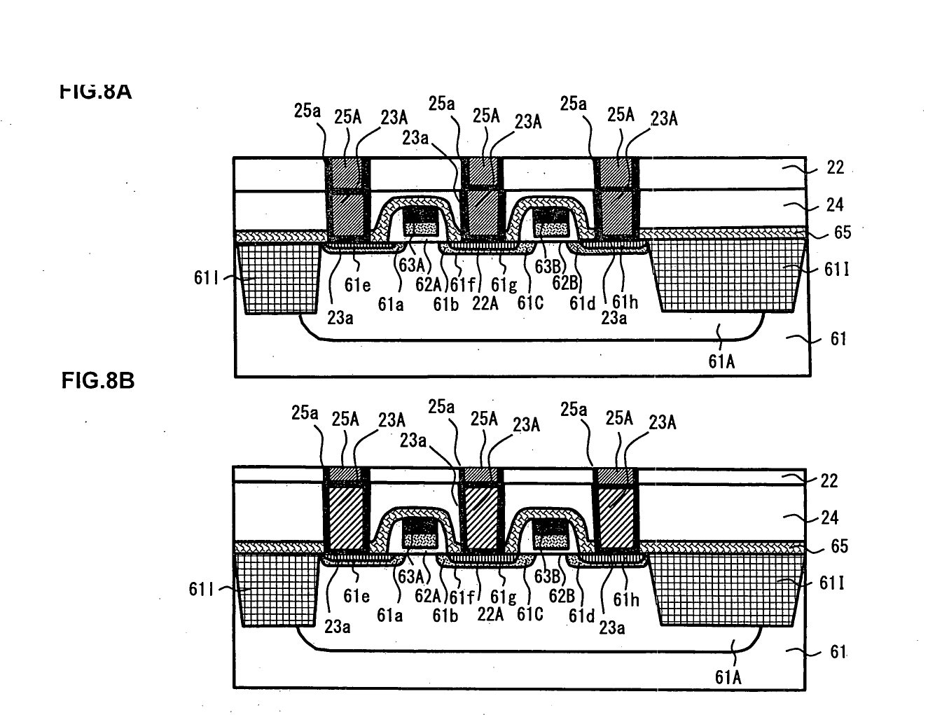

FIGS. 8A and 8B each show an actual cross-sectional structure including the interlayer insulating films 22 and 24 and the via plugs 23A and 25A formed in the steps shown in the above FIGS. 6A to 6I. However, FIG. 8A shows the state at the wafer peripheral portion. FIG. 8B shows the state at the wafer central portion.

The first via plugs 23A are formed in the first interlayer insulating film 22 to be directly connected to diffusion regions 61e, 61f, 61g, and 61h of a first semiconductor element and a second semiconductor element which include, besides the above diffusion regions 61e, 61f, 61g, and 61h, diffusion regions 61a, 61b, 61c, and 61d; gate insulating films 62A and 62B; gate electrodes 63A and 63B; and gate silicide layer 64A and 64B. In addition, the second via plugs 25A are formed in the second interlayer insulating film 24 to be connected to the diffusion regions 61e, 61f, 61g, and 61h of the above first and the second semiconductor elements with the first via plugs 23A interposed therebetween.

As shown in FIGS. 8A and 8B, the length of the via plug 23A is smaller at the wafer peripheral portion than that at the wafer central portion. However, the length of the via plug 25A is larger at the wafer peripheral portion than that at the wafer central portion. Accordingly, it is understood that the total length of the via plugs 23A and 25A at the wafer peripheral portion is equivalent to that at the wafer central portion.

Of course, also in this embodiment, when the CMP apparatus A and the CMP apparatus B are exchanged, that is, when the CMP step in FIG. 6E is performed by the CMP apparatus B, and when the CMP step is performed by the CMP apparatus A after the step shown in FIG. 6I, the total length of the via plugs 23A and 25A at the wafer peripheral portion can also be made equivalent to that at the wafer central portion.

FIGS. 9A and 9B are electron microscope photographs each showing an actual cross-sectional structure including the interlayer insulating films 22 and 24 and the via plugs 23A and 25A which are formed by the steps shown in the above FIGS. 6A to 6I. However, FIG. 9A shows the state of the wafer peripheral portion. FIG. 9B shows the state of the wafer central portion.

As shown in FIGS. 9A and 9B, the length of the via plug 23A is smaller at the wafer peripheral portion than that at the wafer central portion. However, the length of the via plug 25A is larger at the wafer peripheral portion than that at the wafer central portion. Accordingly, it is understood that the total length of the via plugs 23A and 25A at the wafer peripheral portion is equivalent to that at the wafer central portion. Hence, it is understood that the structure including the via plugs 23A and 25A shown in the cross-sectional views of FIGS. 8A and 8B is actually formed.

In this embodiment, the combination between specific polishing recipes has been described by way of example. However, the present invention is not limited to the combination described above, and it is noticeable that without departing from the spirit and the scope of the present invention, various other recipes may be used in combination.

### Second Embodiment

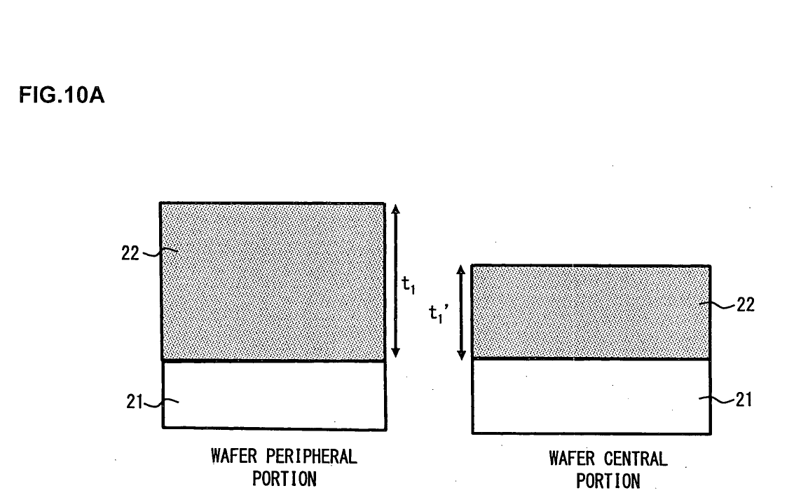

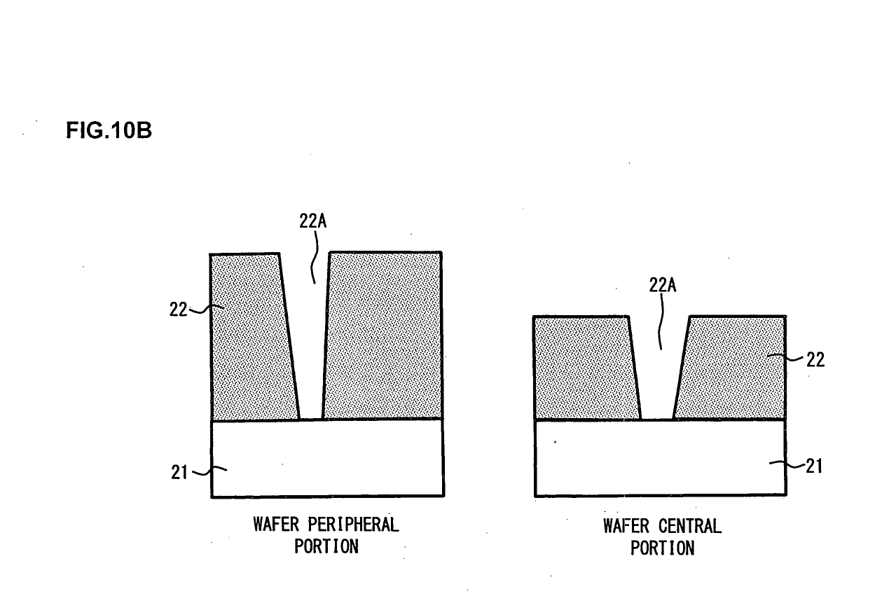

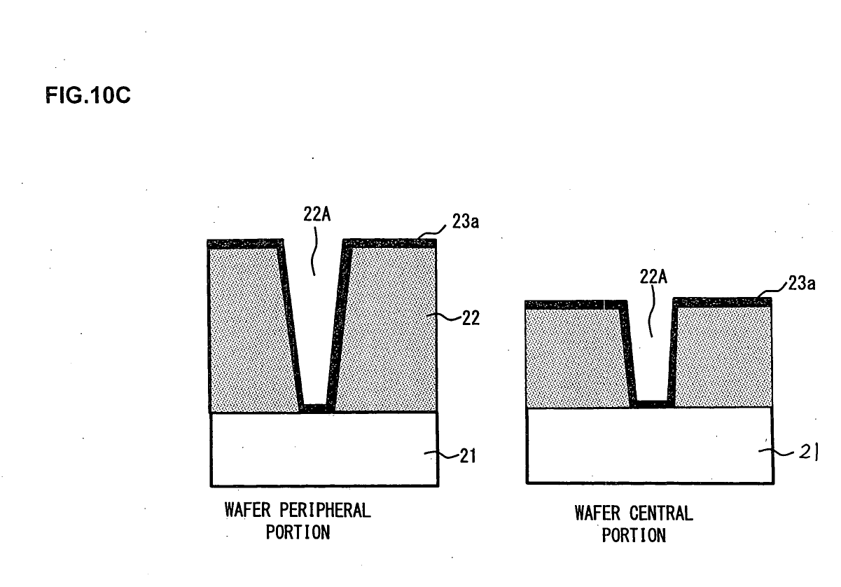

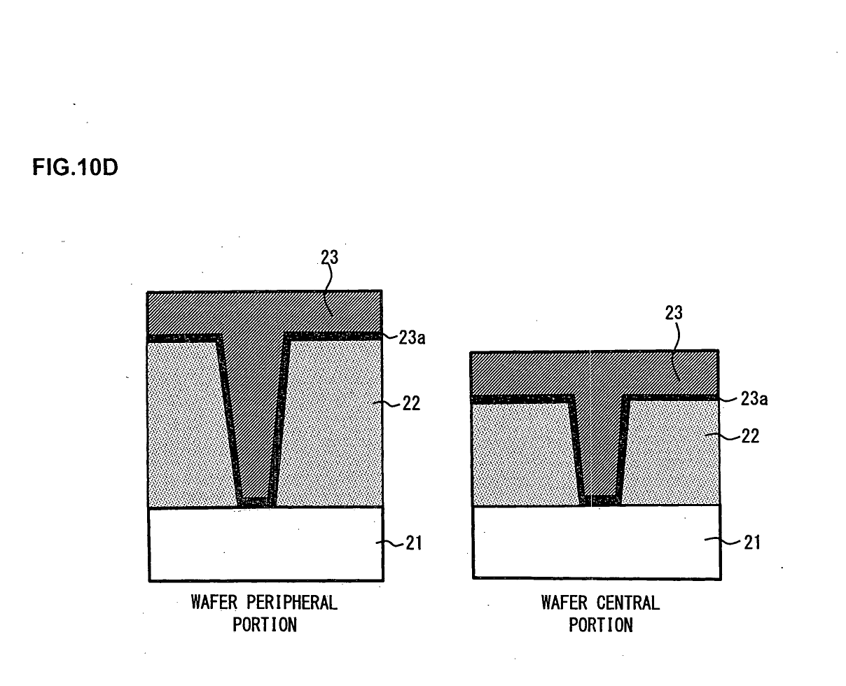

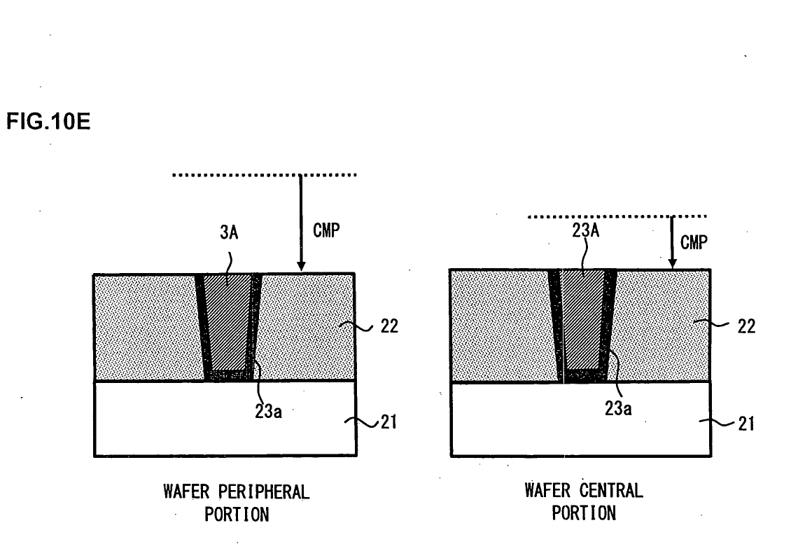

FIGS. 10A to 10D each show a step of manufacturing a semiconductor device of a second embodiment according to the present invention. However, in the figures, the same reference numerals designate the same or corresponding portions as those described above, and description thereof is omitted.

In the process shown in the above FIGS. 6A to 6I, the CMP apparatus A polishing the interlayer insulating film 22 may have an in-plane polishing amount distribution shown by the curve A of FIG. 5A in some cases. In this case, in the step shown in FIG. 6A, the interlayer insulating film 22 can be formed on the substrate 21 so as to have an in-plane thickness distribution which coincides with the in-plane polishing amount distribution shown by the curve A.

As shown in FIG. 10A, in this embodiment, the interlayer insulating film 22 is formed on the substrate 21 to have a large thickness (thickness t1) at the wafer peripheral portion. In addition, the interlayer insulating film 22 is formed on the substrate 21 to have a small thickness (thickness t1′) at the wafer central portion. In the step shown in FIG. 10B, the via holes 22A are formed in the interlayer insulating film 22.

In addition, in the step shown in FIG. 10C, the barrier metal film 23a is deposited on the structure shown in FIG. 10B. The W film 25 is deposited in the step shown in FIG. 10D. Subsequently, in the step shown in FIG. 10E, the W film 25 and the barrier metal film 23a provided thereunder are polished by the CMP apparatus A together with part of the interlayer insulating film 22. In this step, the thickness of the interlayer insulating film 22 can be made uniform from the wafer peripheral portion to the wafer central portion as shown in FIG. 10E.

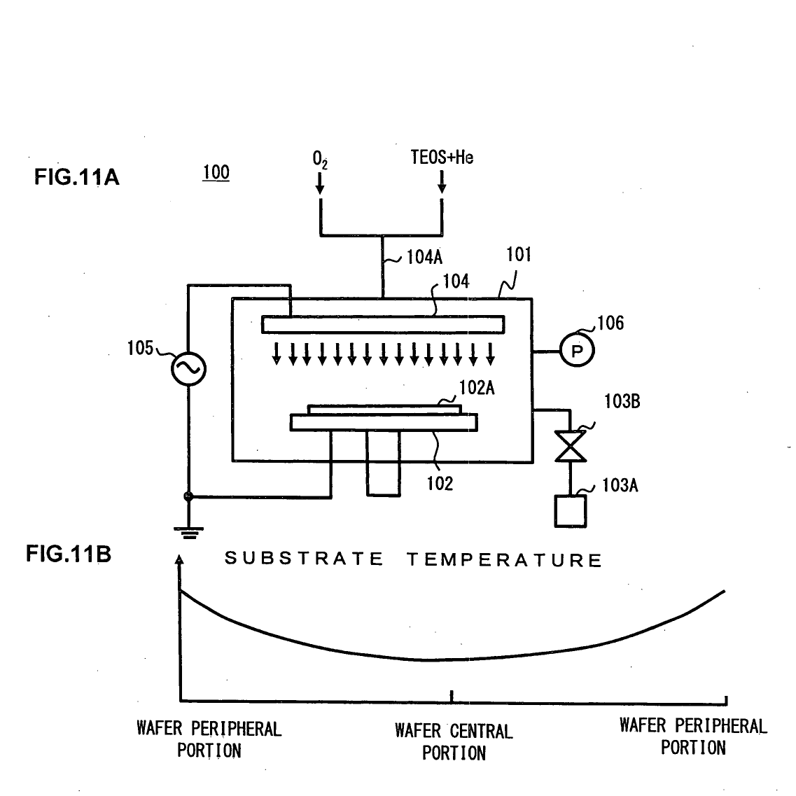

FIGS. 11A and 11B show the structure of a deposition apparatus 100 generating an in-plane thickness distribution of the interlayer insulating film 22 shown in FIG. 10A.

As shown in FIG. 11A, the deposition apparatus 100 is a plasma CVD apparatus. The deposition apparatus 100 has a substrate stage 102 receiving an object substrate 102A. In addition, the deposition apparatus 100 has a process chamber 101 which is evacuated by a vacuum pump 103A through an exhaust valve 103B. In the process chamber 101, a shower head 104 supplying process gases is provided to face the object substrate 102A received on the substrate stage 102.

An oxygen gas and TEOS used as a raw material are supplied to the shower head 104 together with a plasma gas, such as a He gas, via a raw-material supply line 104A. In addition, by applying high frequency using a high-frequency source 105 to the shower head 104, plasma is generated in the process chamber 101. As a result, TEOS used as a raw material is decomposed in the plasma, and a desired interlayer insulating film is deposited on the object substrate 102A.

In addition, in the plasma CVD apparatus shown in FIG. 11A has a pressure meter 106 monitoring the pressure inside the process chamber 101. Furthermore, in the substrate stage 102, a heating mechanism (not shown) heating the object substrate 102A to a desired substrate temperature is provided.

In this embodiment, in the deposition apparatus 100 shown in FIG. 11A, an in-plane distribution of the substrate temperature is generated in the substrate stage 102 as shown in FIG. 11B. In general, in a deposition apparatus forming a film by a CVD method, heating portions are provided in the substrate stage 102 and are independently driven, so that a uniform in-plane distribution of the substrate temperature is realized.

On the other hand, according to the present invention, the heating portions in the substrate stage 102 are driven intentionally to generate the in-plane distribution of the substrate temperature.

As shown in FIG. 11B, the temperature of the object substrate 102A is high at a peripheral portion (wafer peripheral portion) and is low at a central portion (wafer central portion). Hence, the deposition of the interlayer insulating film can be facilitated at the wafer peripheral portion so as to increase the thickness as compared to that at the wafer central portion.

In a manner similar to that described above, the interlayer insulating film 24 to be polished by the CMP apparatus B is formed to have an in-plane thickness distribution in which the thickness is small at the wafer peripheral portion and is large at the wafer central portion. Subsequently, in the CMP step performed after the step shown in FIG. 6I, by polishing using the CMP apparatus B, the thickness of the interlayer insulating film 24 can be made uniform from the wafer peripheral portion to the wafer central portion. In this case, an in-plane distribution of the surface temperature opposite to that shown in FIG. 11B may be generated in the deposition apparatus 100 shown in FIG. 11A so that the substrate temperature is high at the wafer central portion and is low at the wafer peripheral portion.

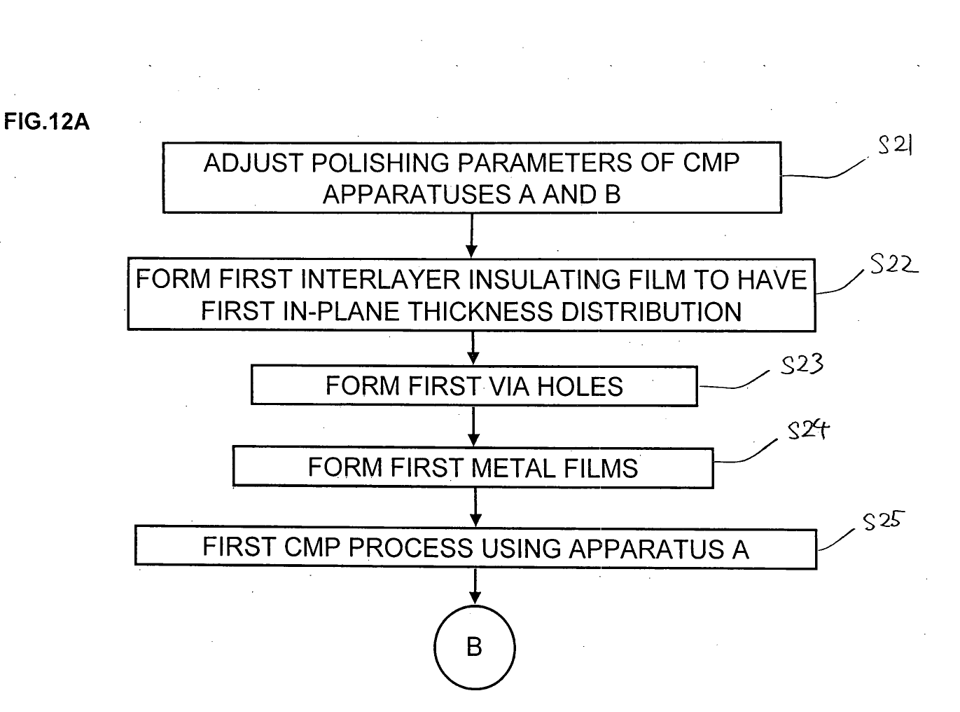

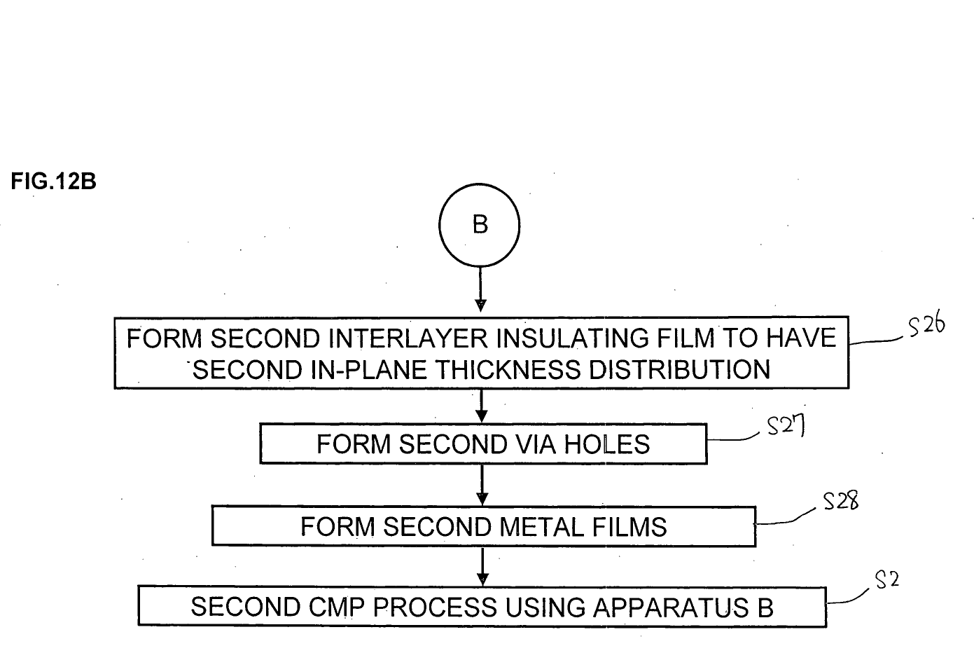

FIGS. 12A and 12B are schematic flowcharts of the second embodiment according to the present invention.

As shown in FIG. 12A, first, in Step S21 of this embodiment, the in-plane polishing amount distributions of the CMP apparatuses A and B used in the CMP steps for the interlayer insulating films 22 and 24 are obtained. Next, in Step S22, corresponding to the step shown in FIG. 6A, the first interlayer insulating film 22 is formed on the substrate so as to have an in-plane thickness distribution which compensates for the in-plane polishing amount distribution of the CMP apparatus A. In Step S23, corresponding to the step shown in FIG. 6B, the via holes 22A are formed in the interlayer insulating film 22.

Furthermore, in Step S24, corresponding to the steps shown in the above FIGS. 6C and 6D, the barrier metal film 23a and the W film 23 are formed. In Step S25, the W film 23 and the barrier metal film 23a are polished by a CMP method using the CMP apparatus A, so that the structure shown in FIG. 6E is formed.

Next, in Step S26 shown in FIG. 12B, corresponding to the step shown in FIG. 6F, the interlayer insulating film 24 is formed on the structure shown in FIG. 6E so as to compensate for the in-plane polishing amount distribution by the CMP apparatus B. In Step S27, corresponding to the step shown in FIG. 6G, the via holes 24A are formed in the interlayer insulating film 24.

Furthermore, in Step S28, corresponding to the steps shown in FIGS. 6H and 6I, the barrier metal film 25a and the W film 25 are formed on the structure shown in FIG. 6G. In addition, in Step S29, the W film 25 and the barrier metal film 25a shown in FIG. 6I are polished by a CMP method using the CMP apparatus B.

In this embodiment, in Step S21, the first interlayer insulating film 22 is formed to have an in-plane thickness distribution so as to compensate for the in-plane polishing amount distribution of the CMP apparatus A. Hence, the interlayer insulating film 22 has an approximately uniform thickness from the wafer peripheral portion to the wafer central portion. In the same manner as described above, in Step S26, the second interlayer insulating film 24 is formed to have an in-plane thickness distribution so as to compensate for the in-plane polishing amount distribution of the CMP apparatus B. Hence, the interlayer insulating film 24 has an approximately uniform thickness from the wafer peripheral portion to the wafer central portion. As a result, the total thickness of the interlayer insulating films 22 and 24 after the CMP step performed in Step S29 has an approximately uniform thickness from the wafer peripheral portion to the wafer central portion.

Of course, in this embodiment, the CMP apparatus A and the CMP apparatus B may be exchanged. That is, the CMP step shown in FIG. 6E can be performed by the CMP apparatus B and the CMP step after the step shown in FIG. 6I can be performed by the CMP apparatus A.

### Third Embodiment

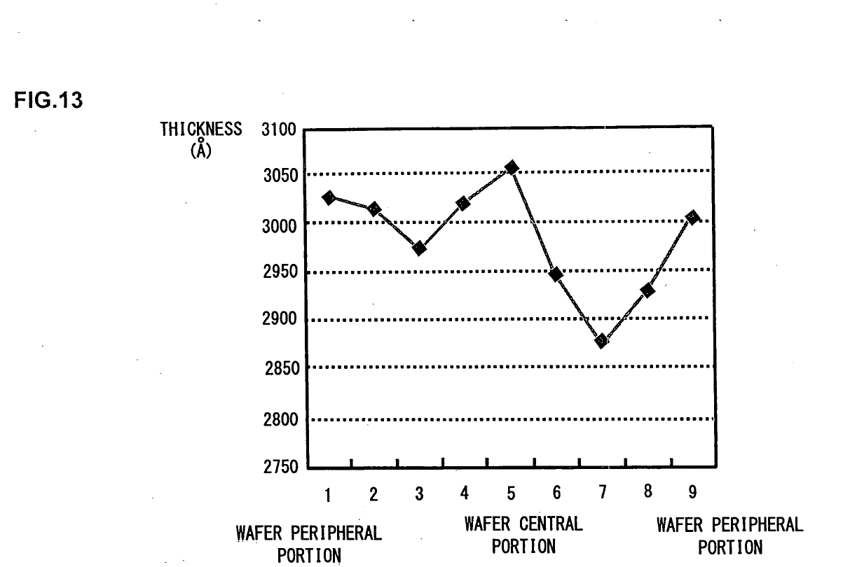

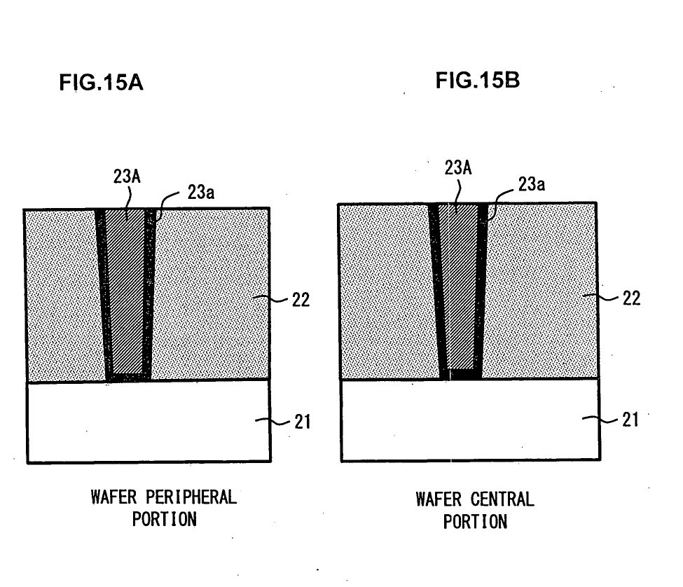

Next, the third embodiment of the present invention will be described with reference to FIGS. 13, 14A to 14C, 15A, and 15B.

In the steps shown in FIG. 6D or 6I, the W film 23 or 25 formed on the corresponding interlayer insulating film may have an in-plane thickness distribution in some cases.

FIG. 13 is a graph showing an example of an in-plane thickness distribution which was actually observed when a W film was formed on the interlayer insulating film 22 or 24 to have an average thickness of 300 nm under conditions shown in Table 1.

TABLE 1

| | Time | Press | Temp | WF₆ | ClF₃ | Ar | SiH₄ | H₂ | N₂ |
|---|---|---|---|---|---|---|---|---|---|
| Step | (sec) | (Pa) | (° C.) | (sccm) | (sccm) | (sccm) | (sccm) | (sccm) | (sccm) |
| 1 | 86 | 2667 | 410 | 15 | 0 | 800 | 4 | 0 | 600 |
| 2 | 15 | 2667 | 410 | 70 | 0 | 900 | 0 | 1500 | 100 |
| 3 | 92 | 2667 | 410 | 90 | 0 | 900 | 0 | 750 | 100 |

As shown Table 1, the deposition of the W film was performed at a substrate temperature of 410° C. by three steps, that is, by a nuclei generation step, a passivation step, and a via-hole filling step. Hence, as shown in FIG. 13, it is understood that the W film 23 or 25 formed on the interlayer insulating film 22 or 24, respectively, had an in-plane thickness distribution.

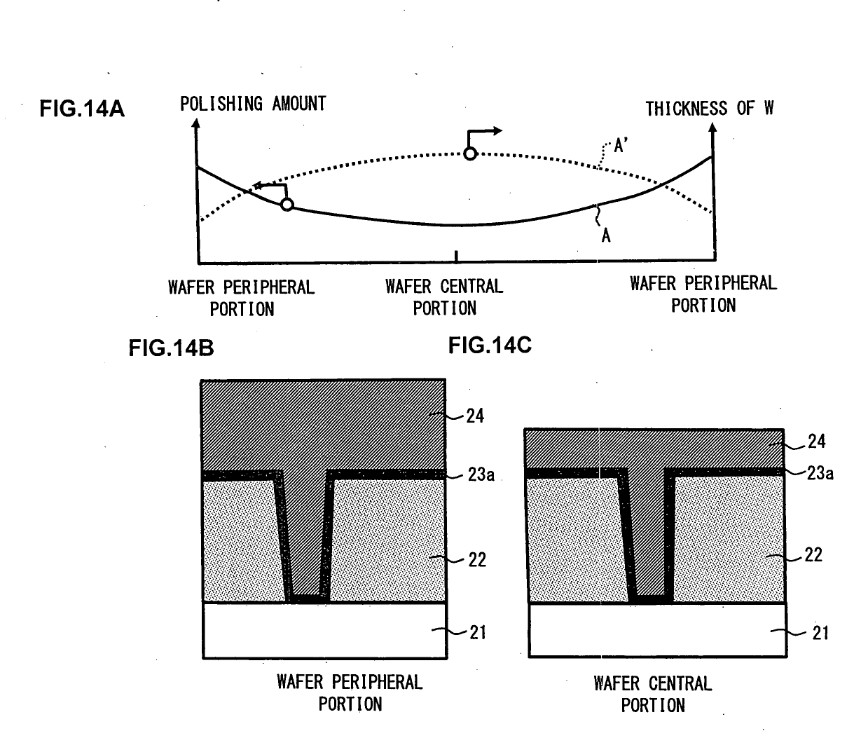

Accordingly, in this embodiment, when the in-plane polishing amount distribution shown by a solid line A of FIG. 14A is generated, for example, in the CMP step shown in FIG. 6E, the W film 23 is formed to have an in-plane thickness distribution shown by a dotted line A′ of FIG. 14A. Accordingly, the in-plane thickness distribution of the W film 23 caused by the in-plane polishing amount distribution in the CMP step can be compensated.

That is, as shown in FIGS. 14B and 14C, the W film 23 is formed on the interlayer insulating film 22 to have a large thickness at the wafer peripheral portion and have a small thickness at the wafer central portion. Accordingly, by the CMP step shown in FIG. 6E, as shown in FIGS. 14B and 14c, the thickness of the interlayer insulating film 22 is made approximately uniform from the peripheral portion to the central portion of the wafer 21.

The thickness distribution of the W film as described above can be obtained by controlling the in-plane distribution of the substrate temperature in the CVD apparatus used for deposition of the W film in a manner similar to that described with reference to FIG. 11.

Although the description is omitted, in the W film 25 formed on the interlayer insulating film 24 as shown in FIG. 6I, a complimentary in-plane thickness distribution is generated based on the in-plane polishing amount distribution of the CMP apparatus B used in the CMP step of the interlayer insulating film 24. As a result, in the structure obtained by the CMP step performed after the step shown in FIG. 6I, the thickness of the W film 25, that is, the thickness of the interlayer insulating film 24, can be made approximately uniform from the wafer peripheral portion to the wafer central portion.

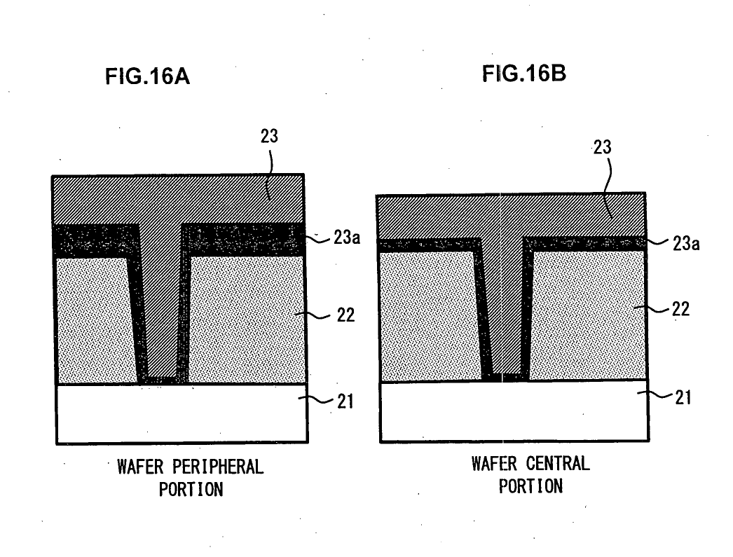

In addition, according to this embodiment, in the step shown in FIG. 6C, the thickness of the barrier metal film 23a may be formed to have an in-plane distribution in which the thickness is large at the wafer peripheral portion and is small at the wafer central portion as shown in FIGS. 16A and 16B so as to be complementary to the in-plane polishing amount distribution of the CMP apparatus A.

In addition, although being not shown in the figure, in the step shown in FIG. 6H, the thickness of the barrier metal film 25a may be formed to have an in-plane distribution in which the thickness is small at the wafer peripheral portion and is large at the wafer central portion so as to be complementary to the in-plane polishing amount distribution of the CMP apparatus B.

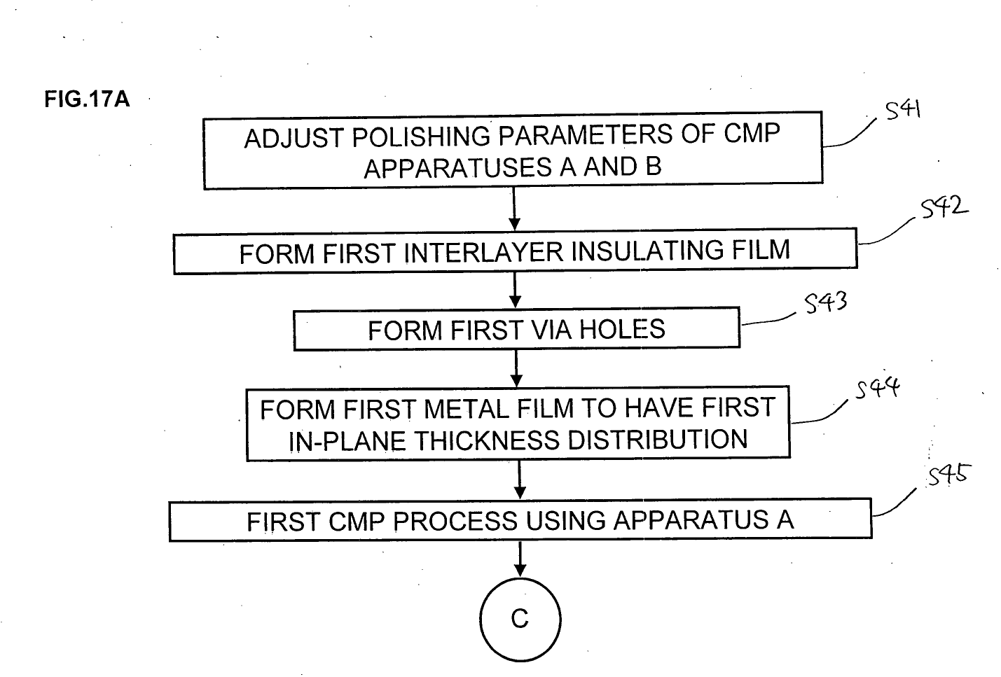

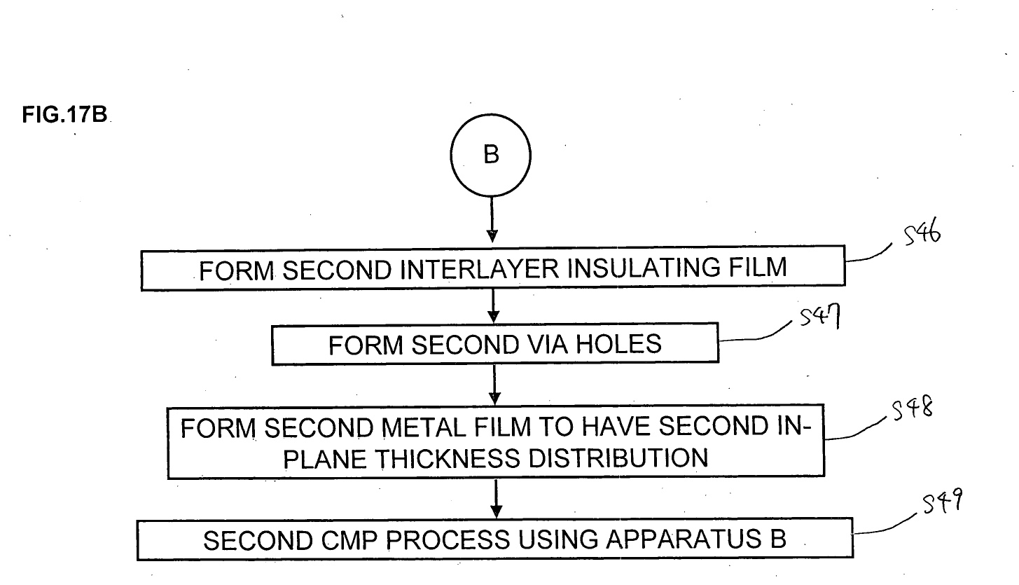

FIGS. 17A and 17B are schematic flowcharts of the third embodiment according to the present invention.

As shown in FIG. 17A, in this embodiment, the in-plane polishing amount distributions of the CMP apparatuses A and B used in the CMP step of the W film 23 are first obtained in Step S41. Next, in Step S42, corresponding to the step shown in FIG. 6A, the first interlayer insulating film 22 is formed on the substrate. Furthermore, in Step S43, corresponding to the step shown in FIG. 6B, the via holes 22A are formed in the first interlayer insulating film 22.

In addition, in Step S44, corresponding to the steps shown in FIGS. 6C and 6D, the barrier metal film 23a and the W film 23 are formed. In Step S45, the W film 23 and the barrier metal film 23a are polished by a CMP method using the CMP apparatus A, so that the structure shown in FIG. 6E is formed. In this embodiment, in Step S44, the barrier metal film 23a or the W film 23 is formed to have an in-plane thickness distribution so as to compensate for the in-plane polishing amount distribution of the above CMP apparatus A. As a result, in the CMP step of Step S45, the interlayer insulating film 22 is formed to have a uniform thickness over the entire wafer surface.

Next, in Step S46 shown in FIG. 17B, corresponding to the step shown in FIG. 6F, the interlayer insulating film 24 is formed on the structure shown in FIG. 6E. In Step S47, corresponding to the step shown in FIG. 6G, the via holes 24A are formed in the interlayer insulating film 24.

Furthermore, in Step S48, corresponding to the steps shown in FIGS. 6H and 6I, the barrier metal film 25a and the W film 25 are formed on the structure shown in FIG. 6G. In addition, in Step S49, the W film 25 and the barrier metal film 25a are polished by a CMP method using the CMP apparatus B.

In Step S48 of this embodiment, the barrier metal film 25a and/or the W film 25 is formed to have an in-plane thickness distribution so as to compensate for the in-plane polishing amount distribution of the CMP apparatus B. As a result, by the CMP step in Step S49, the barrier metal film 25a and/or the W film 25 is formed to have a uniform thickness over the entire wafer surface.

Of course, also in this embodiment, the CMP apparatus A and the CMP apparatus B may be exchanged. That is, the CMP step shown in FIG. 6E can be performed by the CMP apparatus B and the CMP step performed after the step shown in FIG. 6I can be performed by the CMP apparatus A.

The first to the third embodiment described above are effective to a method for manufacturing a semiconductor device including a step of forming via plugs in an interlayer insulating film by a damascene method, such as a method for manufacturing the ferroelectric memory described with reference to FIG. 1.

In the example shown in FIG. 1, the total length of the via plugs 67A and 69A or the total length of the via plugs 67C and 69C of a chip obtained from the wafer peripheral portion can be made approximately equivalent to that of a chip obtained from the wafer central portion. In addition, the total length of the via plug 67B and the via plug 84B of a chip obtained from the wafer peripheral portion can be made approximately equivalent to that of a chip obtained from the wafer central portion.

In addition, according to the second and the third embodiments, as for the individual via plugs, the length of a via plug of a chip obtained from the wafer peripheral portion can be made approximately equivalent to that of a chip obtained from the wafer central portion.

In addition, besides the ferroelectric memory described with reference to FIG. 1, the present invention can be applied to a method for manufacturing any types of semiconductor devices, such as a dynamic random access memory (DRAM) and a logic semiconductor device, including via plugs formed by a damascene method.

Although the preferable embodiments according to the present invention has been described by way of example, the present invention is not limited to any of the particular embodiments described above, and various changes and modifications may be made without departing from the spirit and the scope of the present invention.

What is claimed is:

1. A semiconductor device, comprising:
a semiconductor wafer;
a first interlayer insulating film formed over the semiconductor wafer;
a first group of via plugs formed in the first interlayer insulating film;
a second interlayer insulating film formed in the first interlayer insulating film; and
a second group of via plugs formed in the second interlayer insulating film;
wherein the first interlayer insulating film has a first thickness at a central portion of the semiconductor wafer and the first interlayer insulating film has a second thickness being different from the first thickness at a peripheral portion of the semiconductor wafer; and
the second interlayer insulating film has a third thickness at a central portion of the semiconductor wafer and the second interlayer insulating film has a fourth thickness being different from the third thickness at the peripheral portion of the semiconductor wafer.

2. The semiconductor device according to claim 1, further comprising:
a multilayer wiring structure formed on the second interlayer insulating film.

3. The semiconductor device according to claim 1, further comprising:
an oxygen barrier layer is formed between the first interlayer insulating film and the second interlayer insulating film.

4. The semiconductor device according to claim 1, further comprising:
a ferroelectric capacitor is formed on the oxygen barrier.

5. The semiconductor device according to claim 1, further comprising:
a hydrogen barrier layer formed on the second interlayer insulating layer.

6. A method for manufacturing a semiconductor device, comprising:
forming a first interlayer insulating film over a semiconductor wafer;
polishing the first interlayer insulating film under a first condition by a chemical mechanical polishing method;
forming a second interlayer insulating film on the first interlayer insulating film; and
polishing the second interlayer insulating film under a second condition by a chemical mechanical polishing method;
wherein the first condition and the second condition is set such that a total thickness of the first interlayer insulating film and the second interlayer insulating film is an approximately uniform between the semiconductor wafer central portion and the semiconductor wafer peripheral portion.

7. The method according to claim 6, further comprising:
obtaining a first in-plane thickness distribution of polishing amount occurred by the chemical mechanical polishing of the first interlayer insulating film, and a second in-plane thickness distribution of polishing amount occurred by the chemical mechanical polishing of the second interlayer insulating film before the chemical mechanical polishing of the first interlayer insulating film, the first condition and the second condition are set so that the first in-plane thickness distribution and the second in-plane thickness distribution is approximately complementary.

8. The method according to claim 7, wherein the first condition has a first value such that a wafer in-plane polishing distribution of the polishing amount of the first interlayer insulating film at the center of the wafer, and the wafer in-plane polishing distribution has a second value, being smaller than the first value, at the wafer peripheral portion and the second condition has a third value such that a wafer in-plane polishing distribution of the polishing amount of the second interlayer insulating film has a fourth value at the peripheral of the wafer, being larger than the third value, at the wafer center portion.

9. The method according to claim 6, wherein forming the first interlayer insulating film and the second interlayer insulating film by using tetraethoxysilane.

10. The method according to claim 6, wherein forming a contact hall in the first interlayer insulating film and the second interlayer insulating film.

11. The method according to claim 6, wherein forming a ferroelectric film over the first interlayer insulating film or the second interlayer insulating film.

12. The method for manufacturing a semiconductor device, comprising:
forming a insulating film over a semiconductor wafer;
forming a plurality of contact holes respectively corresponding to a plurality of semiconductor elements formed on the semiconductor wafer;
forming a conductive film at least on inner wall surfaces of the plurality of the contact holes; and
removing the conductive film from a surface of the insulating film by a chemical mechanical polishing method;
wherein forming the insulating film is performed such that the insulating film has an in-plane polishing amount distribution; or
wherein forming the conductive film is performed such that the conductive film has an in-plane polishing amount distribution.

13. The method according to claim 12, wherein the chemical mechanical polishing is performed to have the in-plane polishing amount distribution so that the insulating film has a uniform thickness over the entire semiconductor wafer surface.

14. The method according to claim 12, wherein the chemical mechanical polishing is performed to have the in-plane polishing amount distribution so that the conductive film has a uniform thickness over the entire semiconductor wafer surface.

15. The method according to claim 12, wherein forming the insulating film is performed under the condition such that the in-plane thermal distribution of the semiconductor wafer exists.

16. The method according to claim 12, wherein the conductive film includes a W film.

17. The method according to claim 12, wherein the conductive film includes a barrier metal film covering the inner wall and the bottom surface of the contact hall.

18. The method according to claim 17, wherein the barrier metal film is formed by titan and titanium nitride.

19. The method according to claim 12, wherein a ferroelectric capacitor is formed over the insulating film after the chemical mechanical polishing.
